(19) United States
(12) Patent Application Publication
(10) Pub. No.: US 2006/0234441 A1
(43) Pub. Date: Oct. 19, 2006

(54) Method for preparing a deep trench

(75) Inventors: Jung Wu Chien, Hsinchu (TW); Tsai Chiang Nieh, Jhubei (TW); Ju Cheng Chen, Hsinchu (TW); Chao Hsi Chung, Jhubei (TW)

Correspondence Address: OLIFF & BERRIDGE, PLC, P.O. BOX 19928, ALEXANDRIA, VA, 22320, US

(73) Assignee: PROMOS TECHNOLOGIES INC., Hsinchu (TW)

(21) Appl. No.: 11/222,966

(22) Filed: Sep. 12, 2005

(30) Foreign Application Priority Data
Apr. 13, 2005 (TW) 094111623
Jun. 29, 2005 (TW) 094121824

(51) Int. Cl. H01L 21/465; H01L 21/8242

(52) U.S. Cl. 438/243; 438/696; 438/700

(57) ABSTRACT

A method for preparing a deep trench first forms a trench in a semiconductor substrate and a stacked structure in the trench, wherein the stacked structure includes at least one nitrogen-containing layer. A phosphorous oxide layer is then formed on the surface of the nitrogen-containing layer. The phosphorous oxide is then transformed into an etchant in a steam atmosphere to remove the nitrogen-containing layer in the trench. The phosphorous oxide layer in the trench is then removed, and the nitrogen-containing layer can be effectively removed. The method further comprises forming a plurality of crystallites on a portion of the nitrogen-containing layer before the phosphorous oxide layer is formed on the surface of the nitrogen-containing layer, which allows the formation of a deep trench with a rough inner sidewall.

### BACKGROUND OF THE INVENTION

(A) Field of the Invention

The present invention relates to a method for preparing a deep trench, and more particularly, to a method for preparing a deep trench capable of being applied to a dynamic random access memory (DRAM) with a high integration density.

(B) Description of the Related Art

A memory cell of the DRAM primarily consists of a metal oxide semiconductor field-effect transistor and a capacitor, and there are two types of capacitors: the stacked capacitor and the deep trench capacitor. The stacked capacitor is fabricated directly on the surface of a silicon substrate, while the deep trench capacitor is fabricated inside the silicon substrate. Recently, the integration density of the DRAM has increased rapidly with the innovations in semiconductor process technology, and the size of the memory cell, i.e., the size of the capacitor and the transistor, must be shrunk correspondingly to achieve the purpose of high integration density. Since the capacitance is proportional to the surface area of an electrode of the capacitor, shrinking the size of the capacitor will result in a decrease of the capacitance, which makes it more difficult to correctly read stored data in the cell. Consequently, researchers developed a bottle-shaped deep trench capacitor which increases the inner surface area of the deep trench in the silicon substrate, in turn increasing the surface area of the electrode subsequently formed in the deep trench, thus increasing the capacitance.

FIG. 1 to FIG. 5 illustrate a method for preparing a bottle-shaped deep trench 10 in a silicon substrate 12 according to the prior art. A trench 20 is formed in the silicon substrate 12 at first, and a silicon oxide layer 32, a silicon nitride layer 34, an amorphous silicon layer 36 and a silicon nitride layer 38 are then formed in sequence in the trench 20 and on the surface of the silicon substrate 12. Subsequently, a photoresist layer 40 is formed on the silicon substrate 12, and the photoresist layer 40 fills the trench 20, as shown in FIG. 2.

Referring to FIG. 3, a planarization process is performed to remove a portion of the photoresist layer 40 from the surface of the silicon substrate 12, and an etching process is then performed to remove a portion of the photoresist layer 40 above a predetermined depth 42 of the trench 20. Subsequently, a wet etching process such as dipping the silicon substrate 12 in a buffered hydrofluoric (BHF) acid is performed to selectively remove a portion of the silicon nitride layer 38 not covered by the photoresist layer 40 from the trench 20.

Referring to FIG. 4, a wet etching process is performed to remove the photoresist layer from the trench 20, and a thermal oxidation process is then performed to transform a portion of the amorphous silicon layer 36 not covered by the silicon nitride layer 38 into a mask layer 44. A wet etching process is performed to remove a portion of the silicon oxide layer 32, the silicon nitride layer 34, the amorphous silicon layer 36 and the silicon nitride layer 38 below the predetermined depth 42 of the trench 20. Subsequently, a wet etching process is performed to etch the inner sidewall of the trench 20, i.e., the silicon substrate 12 not covered by the mask layer 44 in the trench 20, to form the bottle-shaped deep trench 10, as shown in FIG. 5.

According to the above description, the prior art method uses the wet etching process to remove the silicon oxide layer 32, the silicon nitride layer 34, the amorphous silicon layer 36 and the silicon nitride layer 38 below the predetermined depth 42 of the trench 20. However, it is becoming more and more difficult to transport the etchant from the aperture of the trench 20 into a region below the predetermined depth 42 of the trench 20 during the wet etching process as the diameter of the trench 20 shrinks, which results in a reduction of the etching rate of the wet etching process. In other words, the etching rate of the wet etching process cannot be effectively increased due to the shrinking diameter and the increasing depth of the trench 20 as the size of the capacitor and the transistor shrinks to achieve the purpose of high integration density.

FIG. 6 to FIG. 10 illustrate another method for preparing a deep trench 110 with a rough inner sidewall in a silicon substrate 112 according to the prior art. Two trenches 116 are formed in the silicon substrate 112 at first, and a bottom electrode 18 is then formed on a lower outer surface of the trench 116. A thermal oxidation process (or a chemical vapor deposition process) and an anisotropic etching process are performed to form a collar oxide layer 120 on an upper inner surface of the trench 116.

Referring to FIG. 7, a masking layer 122 with a thickness between 0.3 and 10 nanometers is formed on the bottom electrode 118 and the collar oxide layer 120 by a low-pressure chemical vapor deposition, thermal oxidation, or a thermal nitridation process. The masking layer 122 can be made of silicon oxide or silicon nitride, and covers the lower inner sidewall of the trench 116. Subsequently, a low-pressure vapor deposition process is performed to form several silicon nanocrystallites 124 on a portion of the mask layer 122, as shown in FIG. 8.

Referring to FIG. 9, a wet etching process is performed using an etchant including phosphoric acid or hydrofluoric acid to selectively remove a portion of the masking layer 122 not covered by the silicon nanocrystallite 124. The masking layer 122 is made of silicon oxide or silicon nitride, while the silicon nanocrystallite 124 is made of silicon. Consequently, using the silicon nanocrystallite 124 as an etching mask, the etchant including the phosphoric acid can selectively remove a portion of the masking layer 122 not covered by the silicon nanocrystallite 124, while the nanocrystallite 124 and another portion of the masking layer 122 below the nanocrystallite 124 can be maintained.

Referring to FIG. 10, another wet etching process is performed using an etchant including hydrofluoric acid and nitric acid to selectively remove the nanocrystallite 124 and etch a portion of the inner sidewall of the trench 116 not covered by the masking layer 122 to form several micro trenches 126. Subsequently, the masking layer 122 is totally removed by the hydrofluoric acid or the phosphoric acid to complete the deep trench 110 with a rough inner sidewall. The inner sidewall of the trench 116 and the nanocrystallite 124 are made of silicon, while the masking layer 122 is made of silicon oxide or silicon nitride. Consequently, the etchant including hydrofluoric acid and nitric acid can use the masking layer 122 as an etching mask to perform the selective etching process that removes the nanocrystallite 124 and etches a portion of the inner sidewall of the trench 116 not covered by the masking layer 122. The deep trench 110 with the rough inner sidewall possesses a higher inner surface area than one without a rough inner sidewall, and a higher inner surface area contributes to increasing the capacitance of a deep trench capacitor subsequently formed in the deep trench 110.

According to the above description, the prior art method uses phosphoric acid with poor fluidity to etch the masking layer 122 in the lower portion of the trench 116. However, it is becoming more and more difficult to transport the phosphoric acid from the aperture of the trench 116 into the lower portion of the trench 116 as the diameter of the trench 116 shrinks, which results in a reduction of the etching rate of the wet etching process. In other words, the etching rate of the wet etching process cannot be effectively increased due to the shrinking diameter and the increasing depth of the trench 116 as the size of the capacitor and the transistor shrinks to achieve the purpose of high integration density.

### SUMMARY OF THE INVENTION

The objective of the present invention is to provide a method for preparing a deep trench capable of being applied to a dynamic random access memory with a high integration density, which uses a reaction between a phosphorous oxide layer and a steam to generate an etchant to remove a nitrogen-containing layer at the bottom portion of a deep trench so as to resolve the conventional, difficult problem of transporting the etchant from the aperture to the bottom portion of the deep trench.

In order to achieve the above-mentioned objective and avoid the problems of the prior art, one embodiment of the present method for preparing a deep trench comprises steps of forming a trench in a semiconductor substrate, forming a stacked structure including at least one nitrogen-containing layer on an inner sidewall of the trench, forming a phosphorous oxide layer on the surface of the nitrogen-containing layer, and transforming a portion of the phosphorous oxide layer in the trench into an etchant to remove a portion of the nitrogen-containing layer contacting the phosphorous oxide layer. To transform the phosphorous oxide layer into the etchant, the semiconductor substrate is placed in a steam atmosphere at a temperature between 700° C. and 1000° C., wherein the phosphorous oxide layer reacts with the steam to generate a phosphoric acid to etch the nitrogen-containing layer.

The present method may further comprise a step of removing a portion of the phosphorous oxide layer above a predetermined depth of the trench, and the subsequently removed portion of the nitrogen-containing layer is below the predetermined depth. To remove the phosphorous oxide layer above the predetermined depth, a dry etching process is performed using etching gases including argon, oxygen and octafluorocyclopentene (C₅F₈). In addition, the phosphorous oxide layer above the predetermined depth may be removed by coating a photoresist layer on the surface of the phosphorous oxide layer, performing a dry etching process to remove a portion of the photoresist layer above the predetermined depth and performing a wet etching process to remove the phosphorous oxide layer above the predetermined depth and the photoresist layer in the trench, wherein the dry etching process uses etching gases including oxygen, nitrogen and carbon tetrafluoride (CF₄).

Another embodiment of the present method for preparing a deep trench comprises steps of forming at least one trench in a semiconductor substrate, forming a nitrogen-containing layer on an inner sidewall of the trench, forming a plurality of crystallites covering a portion of the surface of the nitrogen-containing layer, forming a phosphorous oxide layer on the surface of the nitrogen-containing layer, and transforming the phosphorous oxide layer into an etchant, i.e., the phosphoric acid, to remove a portion of the nitrogen-containing layer not covered by the crystallite. Subsequently, a wet etching process is performed using an etching solution including diluted hydrofluoric acid or buffered hydrofluoric acid to remove the phosphorous oxide layer in the trench. Another wet etching process is then performed using an etching solution including ammonia to selectively etch the silicon crystallite and a portion of the inner sidewall of the trench not covered by the nitrogen-containing layer to form a deep trench with a rough inner sidewall. Consequently, this embodiment allows the formation of a deep trench with a rough inner sidewall to increase the capacitance of a deep trench capacitor subsequently formed in the deep trench.

The prior art needs to transport the etchant from the aperture to the bottom portion of the trench so as to etch the silicon nitride layer at the bottom potion of the trench; therefore, the etching rate of the etching process is limited by the diameter of the trench. On the contrary, the present invention uses a reaction between the phosphorous oxide layer in the trench and a steam to generate an etchant to remove the nitrogen-containing layer on the inner sidewall at the bottom portion of the trench. Since transporting the steam from the aperture to the bottom portion of the trench is not limited by the diameter of the trench, the present invention can effectively resolve the conventional, difficult problem of transporting the etchant to the bottom portion of the trench due to the shrinking of the diameter of the trench.

### BRIEF DESCRIPTION OF THE DRAWINGS

The objectives and advantages of the present invention will become apparent upon reading the following description and upon reference to the accompanying drawings in which:

FIG. 1 to FIG. 5 illustrate a method for preparing a deep trench in a silicon substrate according to the prior art;

FIG. 6 to FIG. 10 illustrate another method for preparing a deep trench in a silicon substrate according to the prior art;

FIG. 11 to FIG. 15 illustrate a method for preparing a deep trench according to a first embodiment of the present invention;

FIG. 16 to FIG. 20 illustrate a method for preparing a deep trench according to a second embodiment of the present invention; and

FIG. 21 to FIG. 26 illustrate a method for preparing a deep trench according to a third embodiment of the present invention.

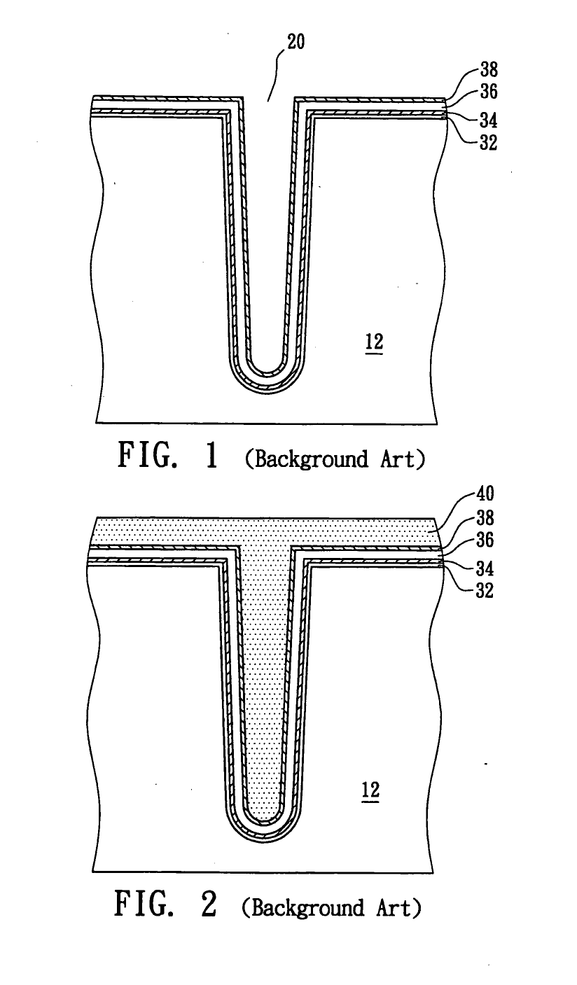

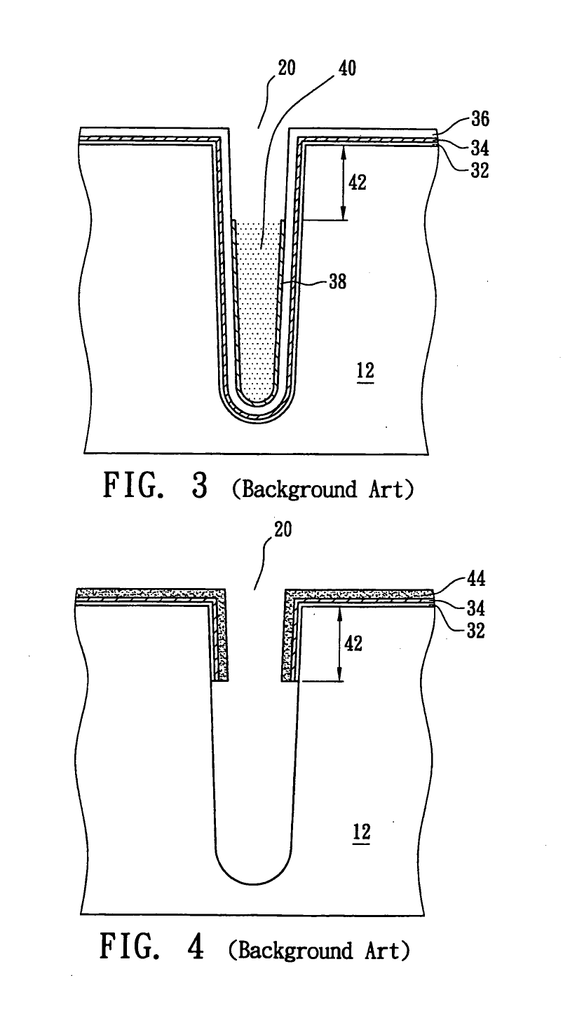

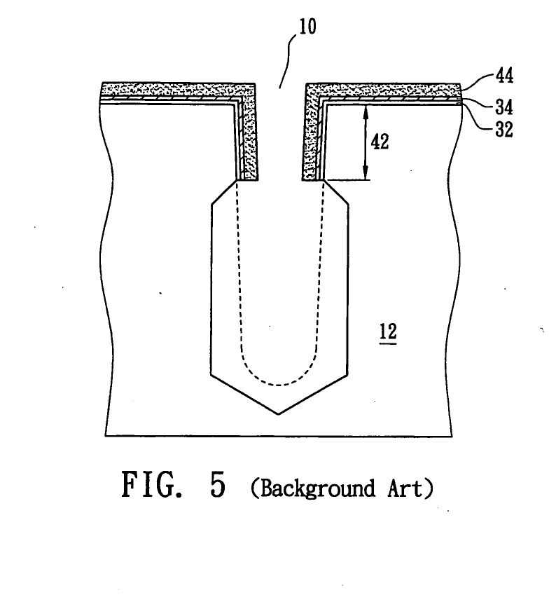

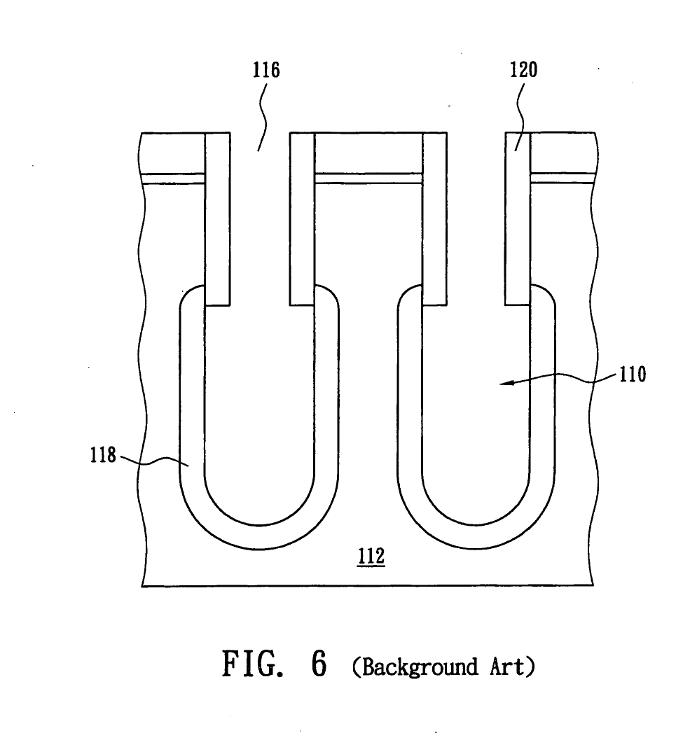

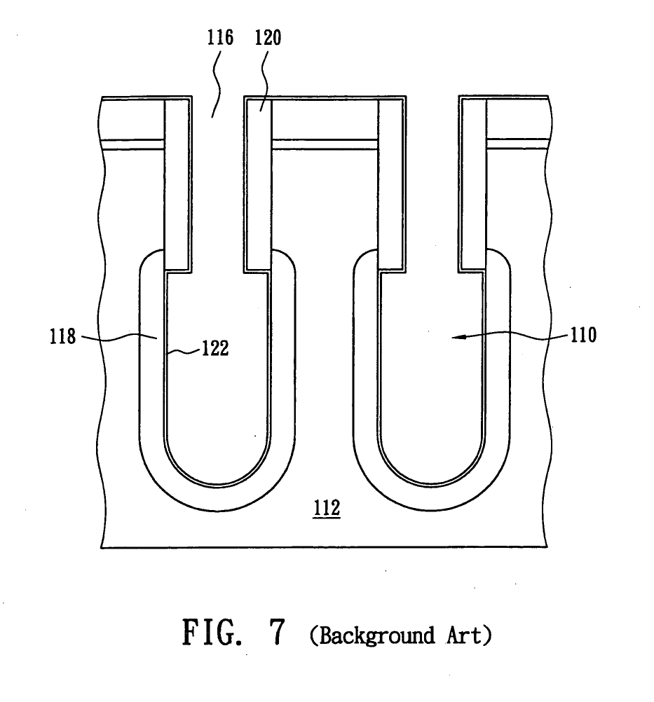

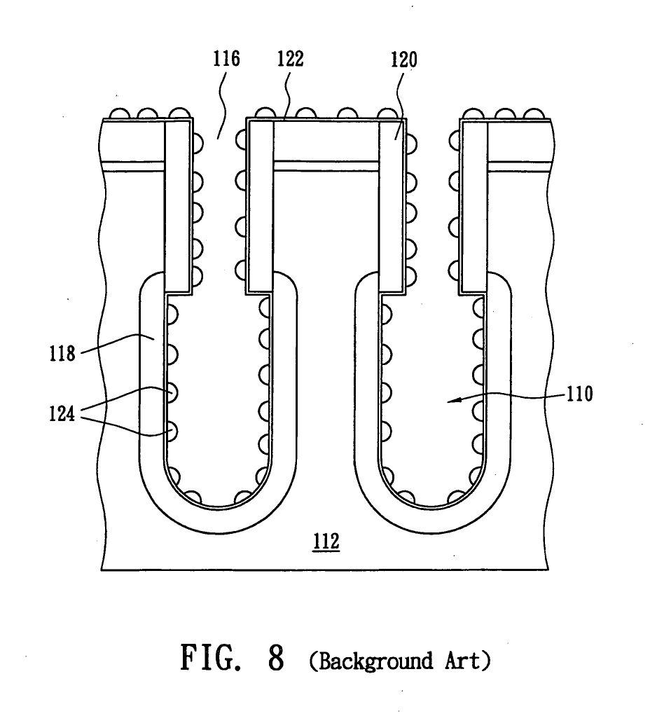

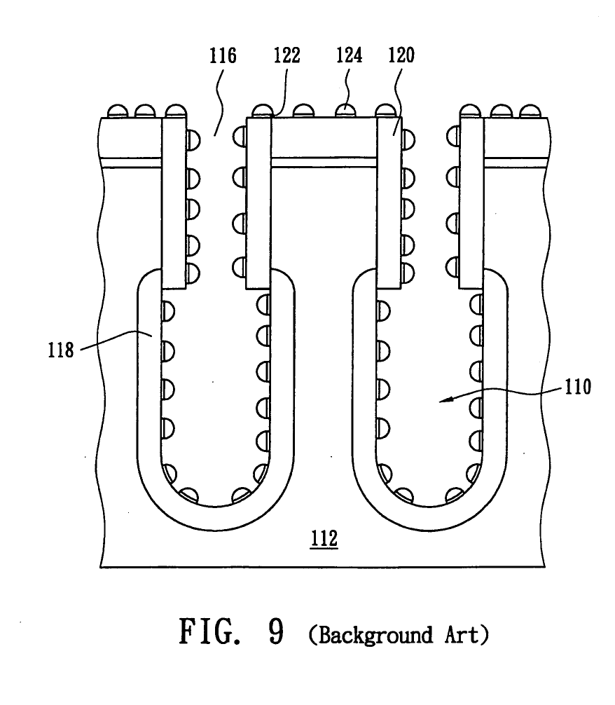

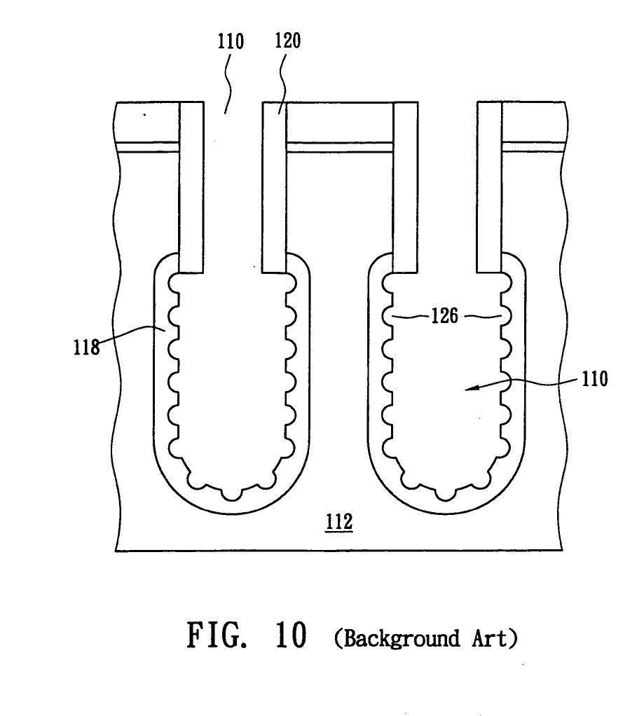

### DETAILED DESCRIPTION OF THE INVENTION

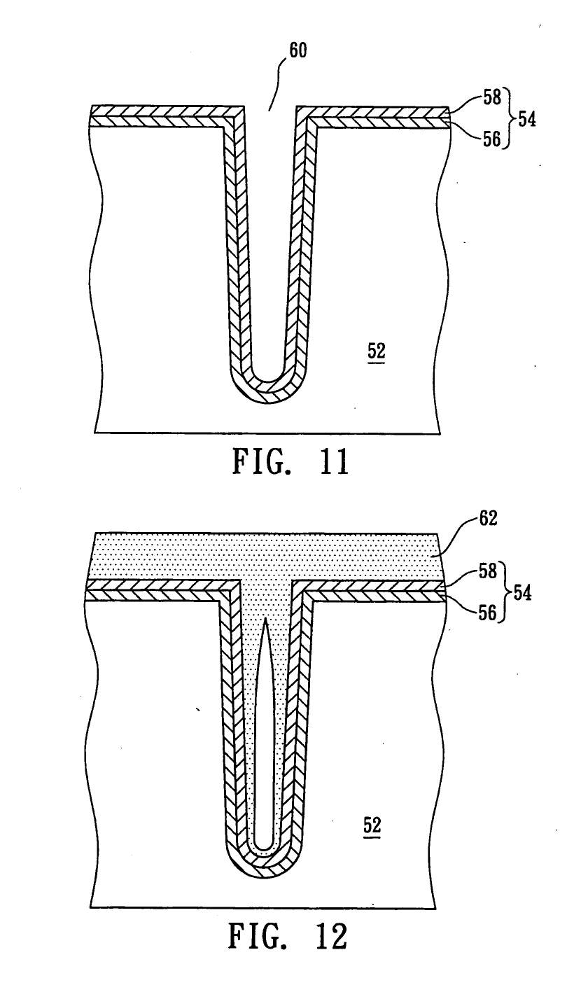

FIG. 11 to FIG. 15 illustrate a method for preparing a bottle-shaped deep trench 50 according to a first embodiment of the present invention. A trench 60 is formed in a semiconductor substrate 52 at first, and a stacked structure 54 including a silicon oxide layer 56 and a nitrogen-containing layer 58 is then formed on the inner sidewall of the trench 60. Subsequently, a phosphorous oxide layer 62 is formed on the surface of the nitrogen-containing layer 58 by a chemical vapor deposition process, as shown in FIG. 12. Preferably, the nitrogen-containing layer 58 is a silicon nitride layer, and the phosphorous oxide layer 62 is a borophosphosilicate glass (BPSG) layer or a phosphosilicate glass (PSG) layer. Since the trench 60 possesses a high aspect ratio and the deposition rate of the chemical vapor deposition process is higher around the aperture than that at the bottom portion and the inner sidewall of the trench 60, a void is likely to form in the trench 60.

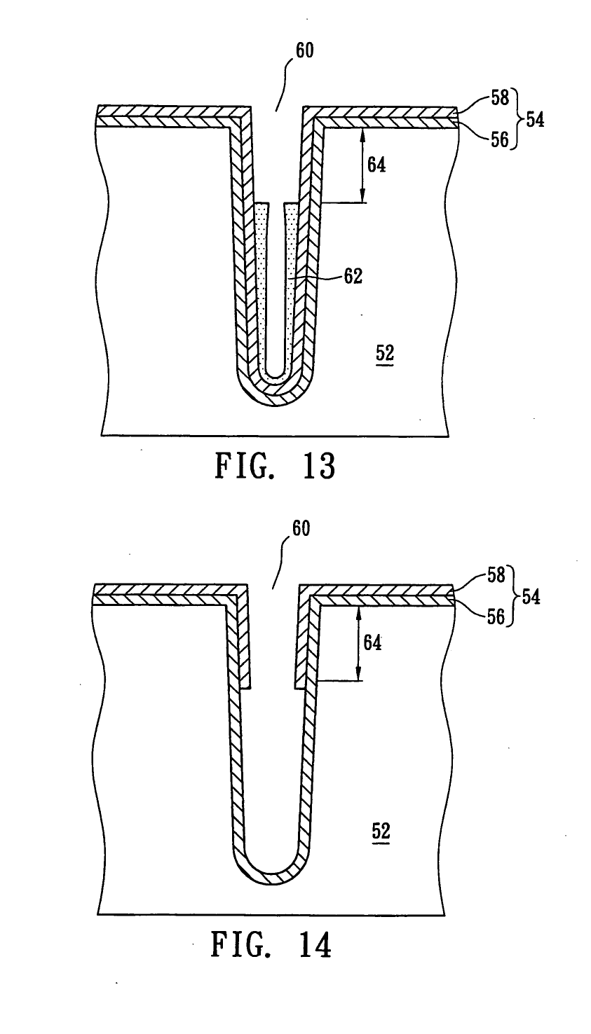

Referring to FIG. 13, a dry etching process is performed to remove a portion of the phosphorous oxide layer 62 above a predetermined depth 64 of the trench 60. Preferably, the dry etching process uses etching gases including argon, oxygen and octafluorocyclopentene. The semiconductor substrate 52 is placed in a steam atmosphere at a temperature between 700° C. and 1000° C. for a period between 30 minutes and 3 hours, and the phosphorous oxide layer 62 in the trench 60 is transformed into an etchant to remove the nitrogen-containing layer 58 below the predetermined depth 64. Particularly, phosphorous in the phosphorous oxide layer 62 reacts with the steam to generate phosphoric acid, which can etch the nitrogen-containing layer 58. Since the phosphorous oxide layer 62 may not be totally transformed into the etchant after the etching process of the nitrogen-containing layer 58 is completed, a buffered oxide etching solution such as diluted hydrofluoric (DHF) acid or buffered hydrofluoric (BHF) acid is used to completely remove the phosphorous oxide layer 62 in the trench 60, as shown in FIG. 14.

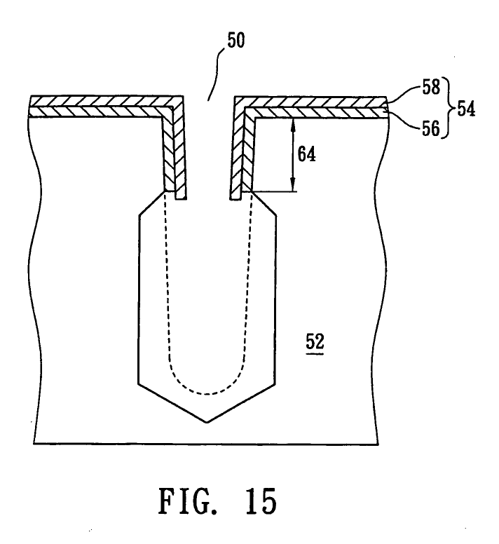

Referring to FIG. 15, a wet etching process is performed to remove the stacked structure 54 below the predetermined depth 64 in the trench 60, i.e., to remove the silicon oxide layer 56 below the predetermined depth 64, wherein the wet etching process uses an etching solution including diluted hydrofluoric acid or buffered hydrofluoric acid. Subsequently, another wet etching process is performed to etch the inner sidewall of the trench 60 below the predetermined depth 64 to complete the bottle-shaped deep trench 50, wherein the wet etching process uses an etching solution including ammonia. The shape of the completed trench according to the above-mentioned process is not limited to be the bottle shape, but depends on the stacked structure 54. The stacked structure 54 may further include a collar dielectric positioned on the upper portion of the trench 60, a non-continuous layer may be formed over the nitrogen-containing layer 58, and a portion of the nitrogen-containing layer 58 may be exposed to contact with the phosphorous oxide layer 62 so that a portion of the nitrogen-containing layer 58 contacting the phosphorous oxide layer 62 will be removed.

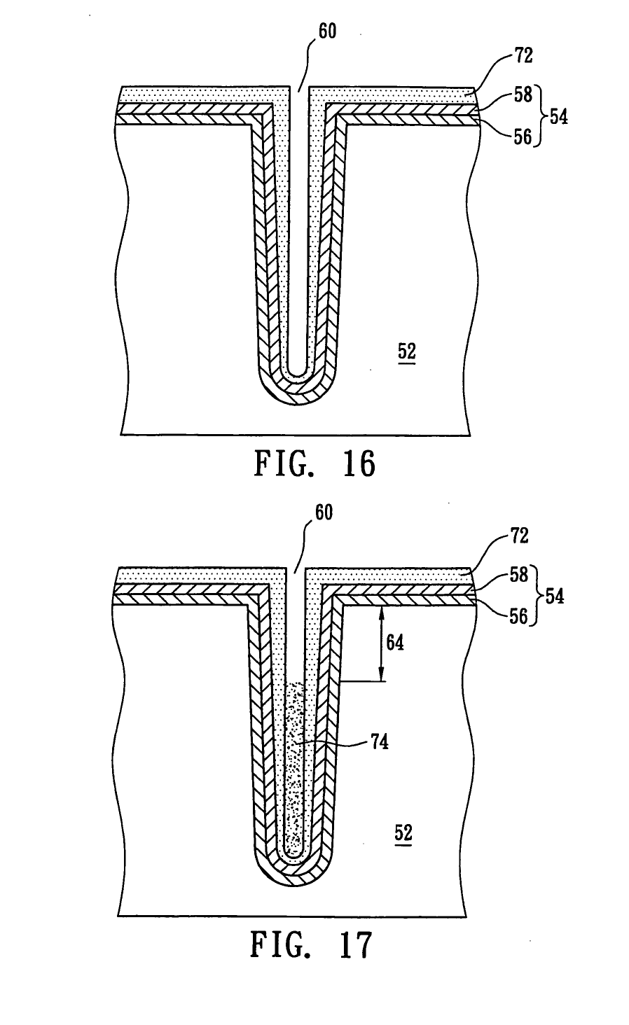

FIG. 16 to FIG. 20 illustrate a method for preparing a bottle-shaped deep trench 70 according to a second embodiment of the present invention. A structure shown in FIG. 11 is formed at first, and a phosphorous oxide layer 72 is then formed on the surface of the nitrogen-containing layer 58 by chemical vapor deposition, as shown in FIG. 16. Compared to the phosphorous oxide layer 62 closing the aperture of the trench 60 in FIG. 12, the phosphorous oxide layer 72 is thinner and does not close the aperture of the trench 60 in FIG. 16.

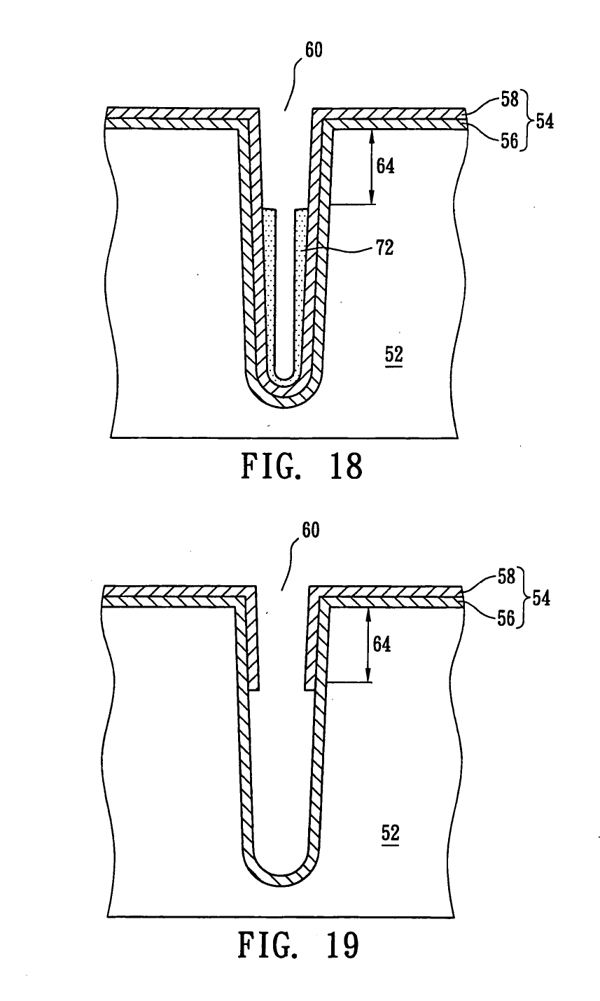

Referring to FIG. 17, a photoresist layer 74 is formed on the surface of the phosphorous oxide layer 72 by a spin-coating process, and a dry etching process is then performed to remove a portion of the photoresist layer 74 above the predetermined depth 64, wherein the dry etching process uses etching gases including oxygen, nitrogen and carbon tetrafluoride. Subsequently, a wet etching process is performed using a buffered oxide etching solution such as diluted hydrofluoric acid or buffered hydrofluoric acid to remove a portion of the phosphorous oxide layer 72 above the predetermined depth 64, and another wet etching process is performed using an etching solution including sulfuric acid to totally remove the photoresist layer 74 inside the trench 60, as shown in FIG. 18.

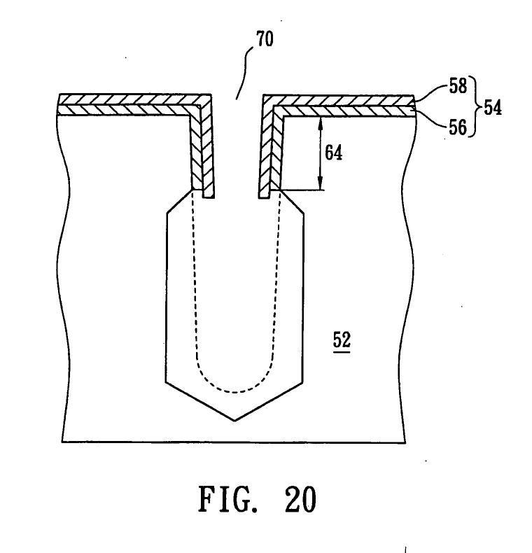

Referring to FIG. 19, the semiconductor substrate 52 is placed in a steam atmosphere at a temperature between 700° C. and 1000° C. for a period between 30 minutes and 3 hours, and the phosphorous oxide layer 72 in the trench 60 is transformed into an etchant to remove the nitrogen-containing layer 58 below the predetermined depth 64. Since the phosphorous oxide layer 72 in the trench 60 may not be totally transformed into the etchant after the etching process is completed, the oxide etching solution is used to etch the phosphorous oxide layer 72 remaining inside the trench 60. Subsequently, a wet etching process is performed using the diluted hydrofluoric acid or buffered hydrofluoric acid as the etchant to remove a portion of the silicon oxide layer 56 below the predetermined depth 64, and another wet etching process is performed using an etching solution including ammonia to etch the inner sidewall of the trench 60 below the predetermined depth 64 to complete the bottle-shaped deep trench 70, as shown in FIG. 20.

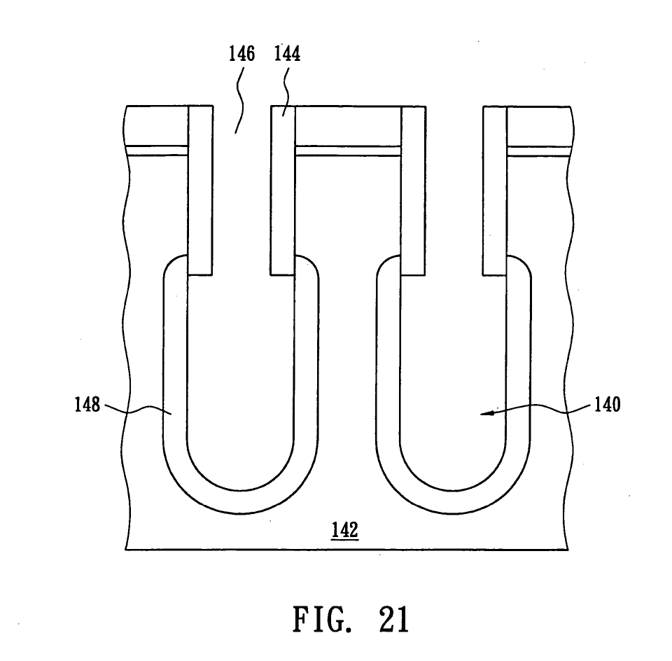

FIG. 21 to FIG. 26 illustrate a method for preparing a deep trench 140 with a rough inner sidewall according to a third embodiment of the present invention. This embodiment first forms two trenches 146 in a semiconductor substrate 142, and a bottom electrode 148 is then formed on a lower outer surface of the trench 146. A thermal oxidation process (or a chemical vapor deposition process) and an anisotropic etching process are performed to form a collar oxide layer 144 on an upper inner surface of the trench 146.

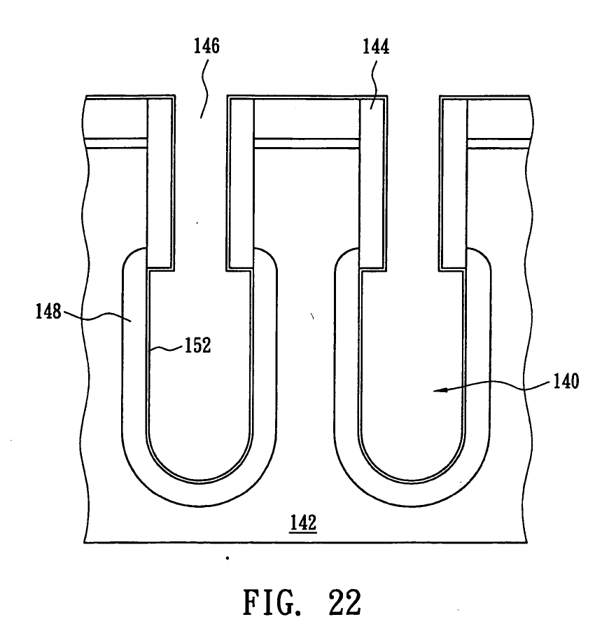

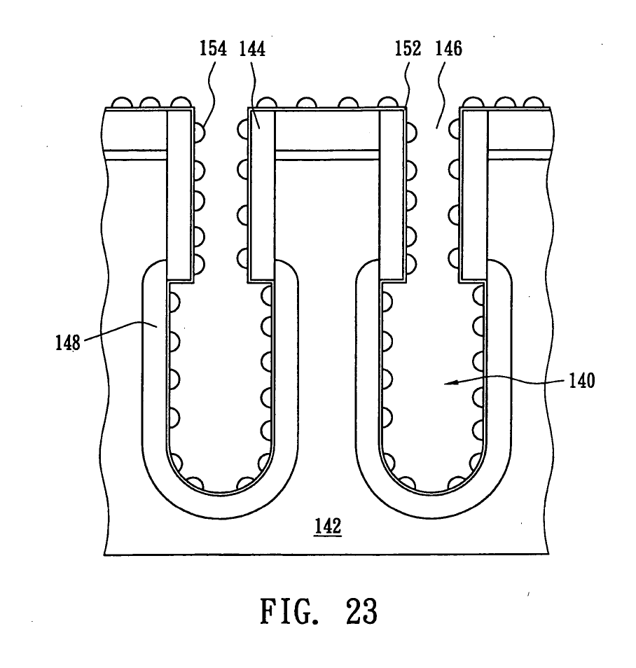

Referring to FIG. 22, a nitrogen-containing layer 152 is formed on the surface of the semiconductor substrate 142 and the inner sidewall of the trench 146 by a chemical vapor deposition process. Subsequently, a plurality of crystallites 154 with a size between 15 and 30 nanometers are formed to cover a portion of the nitrogen-containing layer 152, as shown in FIG. 23. The crystallite 154 can be made of polysilicon, such as a hemi-spherical grain (HSG) form, by the low-pressure chemical vapor deposition process.

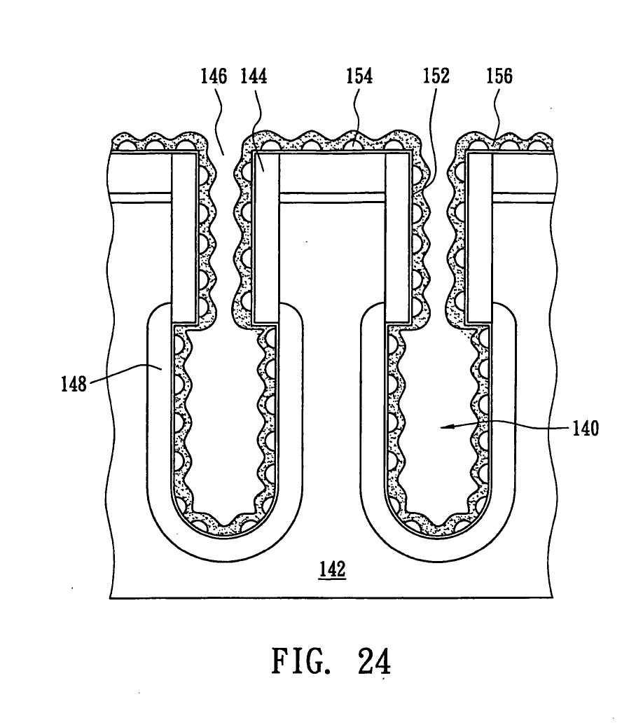

Referring to FIG. 24, a phosphorous oxide layer 156 is formed on the surface of the nitrogen-containing layer 152 by a chemical vapor deposition process, wherein the phosphorous oxide layer 156 covers the crystallite 154 and the nitrogen-containing layer 152. Preferably, the nitrogen-containing layer 152 is a silicon nitride layer, and the phosphorous oxide layer 156 is a borophosphosilicate glass layer or a phosphosilicate glass layer. Subsequently, the semiconductor substrate 142 is placed in a steam atmosphere at a temperature between 700° C. and 1000° C. to transform the phosphorous oxide layer 156 in the trench 146 into an etchant to remove a portion of the nitrogen-containing layer 152 contacting the phosphorous oxide layer 156 directly, i.e., to remove a portion of the nitrogen-containing layer 152 not covered by the crystallite 154. The phosphorous oxide layer 156 is transformed in the phosphoric acid, which uses the crystallite 154 as an etching mask to etch a portion of the nitrogen-containing layer 152 not covered by the crystallite 154, while the crystallite 154 and the other portion of the nitrogen-containing layer 152 covered by the crystallite 154 are maintained.

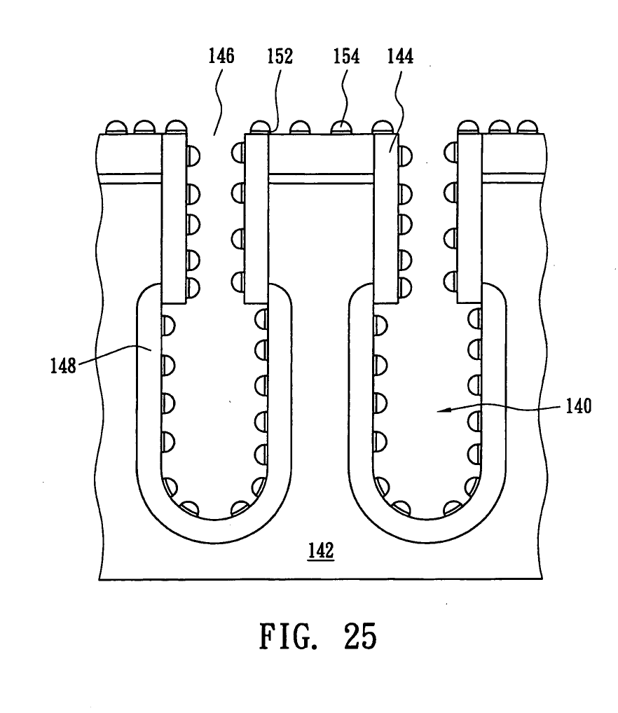

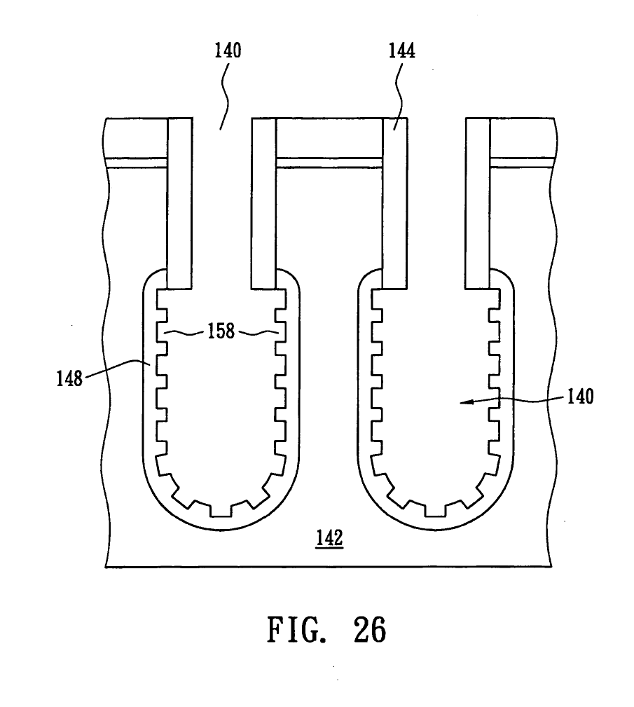

Referring to FIG. 25, a wet etching process is then performed using the diluted hydrofluoric acid or buffered hydrofluoric acid to remove the remaining phosphorous oxide layer 156 that is not transformed into the phosphoric acid. Ammonia is used to perform another wet etching process using the nitrogen-containing layer 152 as an etching mask to etch the inner sidewall of the trench 146 to form several micro trenches 158. Ammonia can selectively remove the silicon, while the silicon nitride remains. Consequently, the wet etching process can selectively remove the polysilicon crystallite 154 and etch a portion of the inner sidewall of the trench 146 not covered by the nitrogen-containing layer 152 to form a rough inner sidewall. Subsequently, the nitrogen-containing layer 152 is totally removed to complete the deep trench 140 with a rough inner sidewall, as shown in FIG. 26. The rough inner sidewall of the trench 146 is used as an electrode of a subsequently formed deep trench capacitor in the deep trench 140, wherein the higher inner surface area of the rough inner sidewall contributes to increasing the capacitance of the deep trench capacitor.

The prior art needs to transport the etchant with poor fluidity from the aperture to the bottom portion of the trench so as to etch the silicon nitride layer at the bottom potion of the trench, and therefore the etching rate of the etching process is limited by the diameter of the trench. On the contrary, the present invention uses a reaction between the phosphorous oxide layer in the trench and a steam to generate an etchant to remove a nitrogen-containing layer on the inner sidewall at the bottom portion of the trench, and the transportation of the steam from the aperture to the bottom portion of the trench is not limited by the diameter of the trench. In other words, placing the semiconductor substrate in a steam atmosphere can transform the phosphorous oxide layer in the trench into the etchant, which is capable of etching the nitrogen-containing layer. Consequently, the present invention need not actually transport the etchant for the nitrogen-containing layer from the aperture to the bottom portion of the trench, and can be applied to prepare a trench with a smaller aperture used in a dynamic random access memory with a high integration density.

The above-described embodiments of the present invention are intended to be illustrative only. Numerous alternative embodiments may be devised by those skilled in the art without departing from the scope of the following claims.

What is claimed is:

1. A method for preparing a deep trench, comprising steps of:
forming at least one trench in a semiconductor substrate;
forming a stacked structure including a nitrogen-containing layer in the trench;
forming a phosphorous oxide layer on the surface of the nitrogen-containing layer; and
transforming the phosphorous oxide layer into an etchant to remove at least a portion of the nitrogen-containing layer of the stacked layer.

2. The method for preparing a deep trench of claim 1, further comprising a step of removing a portion of the phosphorous oxide layer above a predetermined depth of the trench after the step of forming a phosphorous oxide layer on the surface of the nitrogen-containing layer.

3. The method for preparing a deep trench of claim 1, wherein the nitrogen-containing layer is a silicon nitride layer, and the phosphorous oxide layer is a borophosphosilicate glass layer or a phosphosilicate glass layer.

4. The method for preparing a deep trench of claim 1, wherein the step of transforming the phosphorous oxide layer into an etchant is performed by placing the semiconductor substrate in a steam atmosphere.

5. The method for preparing a deep trench of claim 4, wherein the step of transforming the phosphorous oxide layer into an etchant is performed at a temperature between 700° C. and 1000° C.

6. The method for preparing a deep trench of claim 2, wherein the step of removing a portion of the phosphorous oxide layer above a predetermined depth of the trench is performed by a dry etching process.

7. The method for preparing a deep trench of claim 6, wherein the dry etching process uses etching gases including argon, oxygen and octafluorocyclopentene.

8. The method for preparing a deep trench of claim 2, wherein the step of removing a portion of the phosphorous oxide layer above a predetermined depth of the trench comprises:
forming a photoresist layer on the surface of the phosphorous oxide layer;
performing a dry etching process to remove a portion of the photoresist layer above the predetermined depth;
performing a wet etching process to remove the phosphorous oxide layer above the predetermined depth; and
removing the photoresist layer in the trench.

9. The method for preparing a deep trench of claim 8, wherein the dry etching process uses etching gases including oxygen, nitrogen and carbon tetrafluoride.

10. The method for preparing a deep trench of claim 8, wherein the wet etching process uses an etching solution including diluted hydrofluoric acid or buffered hydrofluoric acid.

11. The method for preparing a deep trench of claim 8, wherein the step of removing the photoresist layer in the trench is performed by a wet etching process, and the wet etching process comprises using an etching solution including sulfuric acid.

12. The method for preparing a deep trench of claim 1, wherein the step of forming a phosphorous oxide layer on the surface of the nitrogen-containing layer is performed by a chemical vapor deposition process.

13. The method for preparing a deep trench of claim 2, further comprising steps of:
removing a portion of the stacked structure below the predetermined depth; and
performing a wet etching process to etch an inner sidewall of the trench below the predetermined depth.

14. The method for preparing a deep trench of claim 13, wherein the stacked structure further comprises a silicon oxide layer, and the step of removing a portion of the stacked structure below the predetermined depth is performed by a wet etching process using an etching solution including diluted hydrofluoric acid or buffered hydrofluoric acid.

15. The method for preparing a deep trench of claim 13, wherein the wet etching process uses an etching solution including ammonia.

16. A method for preparing a deep trench, comprising steps of:
forming at least one trench in a semiconductor substrate;
forming a nitrogen-containing layer on an inner sidewall of the trench;
forming a plurality of crystallites covering a portion of the surface of the nitrogen-containing layer;
forming a phosphorous oxide layer on the surface of the nitrogen-containing layer; and
transforming the phosphorous oxide layer into an etchant to remove a portion of the nitrogen-containing layer not covered by the crystallite.

17. The method for preparing a deep trench of claim 16, wherein the crystallite is made of polysilicon.

18. The method for preparing a deep trench of claim 16, wherein the size of the crystallite is between 15 and 30 nanometers.

19. The method for preparing a deep trench of claim 16, wherein the nitrogen-containing layer is a silicon nitride layer, and the phosphorous oxide layer is a borophosphosilicate glass layer or a phosphosilicate glass layer.

20. The method for preparing a deep trench of claim 16, wherein the step of forming a phosphorous oxide layer on the surface of the nitrogen-containing layer is performed by a low-pressure chemical vapor deposition process.

21. The method for preparing a deep trench of claim 16, wherein the step of transforming the phosphorous oxide layer into an etchant is performed by placing the semiconductor substrate in a steam atmosphere.

22. The method for preparing a deep trench of claim 21, wherein the step of transforming the phosphorous oxide layer into an etchant is performed at a temperature between 700° C. and 1000° C.

23. The method for preparing a deep trench of claim 16, further comprising a step of removing the phosphorous oxide layer in the trench by a wet etching process.

24. The method for preparing a deep trench of claim 23, wherein the wet etching process uses an etching solution including diluted hydrofluoric acid or buffered hydrofluoric acid.

25. The method for preparing a deep trench of claim 23, further comprising a step of roughening the inner sidewall of the trench by a wet etching process to etch a portion of the inner sidewall not covered by the nitrogen-containing layer.

26. The method for preparing a deep trench of claim 25, wherein the wet etching process uses an etching solution including ammonia.

27. The method for preparing a deep trench of claim 25, wherein the wet etching process uses a portion of the nitrogen-containing layer covered by the crystallite as an etching mask.

28. The method for preparing a deep trench of claim 25, wherein the roughened inner sidewall of the trench is used as an electrode of a capacitor.
